(19) United States
(12) Patent Application Publication
(10) Pub. No.: US 2025/0160185 A1
(43) Pub. Date: May 15, 2025

(54) DISPLAY DEVICE

(71) Applicant: LG Display Co., Ltd., Seoul (KR)

(72) Inventors: Jung Geun JO, Paju-si (KR); Hong Seop SHIN, Paju-si (KR); Woong Jin SEO, Paju-si (KR); Soo Young YOON, Paju-si (KR)

(21) Appl. No.: 18/936,374

(22) Filed: Nov. 4, 2024

(30) Foreign Application Priority Data
Nov. 13, 2023 (KR) 10-2023-0156233

(51) Int. Cl. H10K 59/80

(52) U.S. Cl. CPC H10K 59/879

(57) ABSTRACT

Disclosed is a display device. The display device includes a substrate in which a first area and a second area adjacent to the first area are defined. The display device includes a first pixel in the first area, and a second pixel in the second area. The first pixel includes at least one second emission area, and the second pixel includes at least one first emission area and at least one second emission area. The first emission area corresponds to a half-spherical lens, and the second emission area corresponds to a half-cylindrical lens. Thus, the second area is configured such that a viewing angle control function is activated.

### CROSS-REFERENCE TO RELATED APPLICATION(S)

This application claims the benefit of Korean Patent Application No. 10-2023-0156233, filed on Nov. 13, 2023, which is hereby incorporated by reference as if fully set forth herein.

### BACKGROUND

### Technical Field

The present disclosure relates to a display device, and more particularly, to a display device capable of controlling a viewing angle.

### Description of the Related Art

With the advancement of technologies in modern society, a display device has been used in various forms to provide users with information. A display device is included not only in electronic display boards that unidirectionally transfer visual information but also in various electronic devices that use advanced technologies to check user input and to provide information in response to the checked input.

For example, a display device may be included in a vehicle to provide various kinds of information to a driver and a passenger of the vehicle. However, a display device of a vehicle needs to properly display content so as not to disturb driving of the vehicle. For example, a display device of a vehicle needs to limit display of content that may distract driver's concentration on driving during driving of the vehicle.

### BRIEF SUMMARY

Accordingly, the present disclosure is directed to a display device that substantially obviates one or more problems due to limitations and disadvantages of the related art.

Various embodiments of embodiments of the present disclosure provide a display device capable of selectively controlling a viewing angle.

Various embodiments of the present disclosure provide a display device exhibiting improved luminous efficiency.

Various embodiments of the present disclosure provide a display device capable of prolonging the lifespan of a light-emitting device.

Various embodiments of the present disclosure provide a display device capable of reducing or minimizing recognition of a boundary between a viewing angle control area and a general area.

The technical benefits to be accomplished by the present disclosure are not limited to the above-mentioned benefits, and other benefits not mentioned herein will be clearly understood by those skilled in the art from the following description.

Additional advantages, benefits, and features of the disclosure will be set forth in part in the description which follows and in part will become apparent to those having ordinary skill in the art upon examination of the following or may be learned from practice of the disclosure. The objects and other advantages of the disclosure may be realized and attained by the structure particularly pointed out in the written description and claims hereof as well as the appended drawings.

To achieve these benefits and other advantages and in accordance with the purpose of the disclosure, as embodied and broadly described herein, a display device includes a first area and a second area adjacent to the first area, a first pixel located in the first area, and a second pixel located in the second area. The first pixel includes at least one second emission area, and the second pixel includes at least one first emission area and at least one second emission area. The first emission area has a half-spherical lens disposed therein, and the second emission area has a half-cylindrical lens disposed therein.

In another aspect of the present disclosure, a display device includes a substrate in which a first area and a second area adjacent to the first area are defined, a first pixel located in the first area, and a second pixel located in the second area. The first pixel and the second pixel are pixels have the same color. Each of the first pixel and the second pixel includes one or more emission areas, and the number of emission areas of the second pixel is greater than the number of emission areas of the first pixel.

In still another aspect of the present disclosure, a display device includes a substrate in which a first area and a second area adjacent to the first area are defined, a first pixel located in the first area, a second pixel located in the second area, and lenses respectively corresponding to the first pixel and the second pixel. The first pixel and the second pixel have the same color. The number of lenses corresponding to the second pixel is greater than the number of lenses corresponding to the first pixel.

The details of other aspects will be included in the detailed description and the drawings below.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a view showing an example of a display device incorporated in a vehicle according to an embodiment of the present disclosure;

FIG. 2 is a cross-sectional view of the display device according to the embodiment of the present disclosure;

FIG. 3 is a cross-sectional view of an emission area of the display device according to the embodiment of the present disclosure;

FIG. 4 is a driving circuit diagram of a pixel according to the embodiment of the present disclosure;

FIGS. 5 and 6 are perspective views of lenses according to the embodiment of the present disclosure;

FIGS. 7 and 8 are diagrams showing optical profiles of the lenses shown in FIGS. 5 and 6;

FIG. 9 is an enlarged plan view of the display device according to the embodiment of the present disclosure;

FIG. 10 is an enlarged plan view of area B shown in FIG. 9;

FIG. 11 is an enlarged plan view of area C shown in FIG. 9;

FIG. 12 is an enlarged plan view of another embodiment of area C shown in FIG. 9; and

FIGS. 13 and 14 are enlarged plan views of the display device according to the embodiment of the present disclosure.

### DETAILED DESCRIPTION

Advantages and features of the present disclosure and methods for achieving the same will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the disclosure to those skilled in the art.

In the drawings for explaining the exemplary embodiments of the present disclosure, for example, the illustrated shape, size, ratio, angle, and number are given by way of example, and thus, are not limited to the disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises,” “includes,” and/or “has,” used in this specification, do not preclude the presence or addition of other elements unless used along with the term “only.” The singular forms are intended to include the plural forms as well, unless the context clearly indicates otherwise.

In the interpretation of constituent elements, the constituent elements are interpreted as including an error range even if there is no explicit description thereof.

In the description of the various embodiments, when describing positional relationships, for example, when the positional relationship between two parts is described using “on,” “above,” “below,” “next to,” or the like, one or more other parts may be located between the two parts unless the term “directly” or “closely” is used.

When an element or layer is referred to as being “on” another element or layer, it may be directly on the other element or layer, or intervening elements or layers may be present.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

It may be understood that, although the terms “first,” “second,” etc., may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

Throughout the specification, the same reference numerals denote the same elements.

Since the size and thickness of each component illustrated in the drawings are represented for convenience of description, the present disclosure is not necessarily limited to the illustrated size and thickness of each component.

The respective features of the various embodiments of the present disclosure may be partially or entirely coupled to and combined with each other, and various technical linkages and modes of operation thereof are possible. These various embodiments may be performed independently of each other or may be performed in association with each other.

Hereinafter, the present disclosure will be described with reference to the drawings.

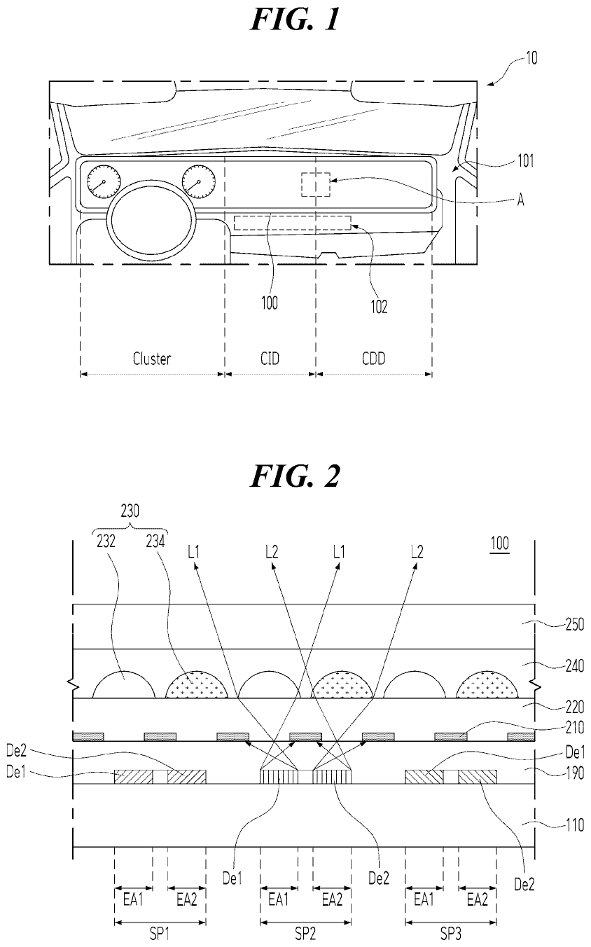

FIG. 1 is a view showing an example of a display device incorporated in a vehicle according to an embodiment of the present disclosure.

A display device 100 may be disposed on at least a portion of a dashboard of a vehicle 10. The dashboard of a vehicle 10 may include components disposed in front of front seats (e.g., a driver's seat and a front passenger seat) of the vehicle 10. For example, input components for operation of various systems (e.g., an air-conditioning system, an audio system, and a navigation system) provided in the vehicle 10 may be disposed on the dashboard of the vehicle 10.

In the embodiment, the display device 100 may be disposed on the dashboard of the vehicle 10 and may serve as an input unit to operate at least some of the aforementioned various systems provided in the vehicle 10. The display device 100 may provide various kinds of information related to the vehicle 10, for example, vehicle driving information (e.g., a current speed of the vehicle, a remaining amount of fuel, and a travel distance) and information about components of the vehicle (e.g., a damage level of a tire).

In the embodiment, the display device 100 may be disposed to extend over the front seats of the vehicle 10, i.e., the driver's seat and the front passenger seat. A user of the display device 100 may include a driver of the vehicle 10 and a passenger in the front passenger seat. Both the driver and the passenger of the vehicle 10 may use the display device 100.

As shown in FIG. 1, a display panel of the display device 100 itself may be incorporated into a body 101 of the vehicle 10. Accordingly, the display device 100 (or the display panel), under normal operation, is not separated or detached from the body 101 of the vehicle 10. However, it may be separated in instances where the display device needs repair.

The body 101 of the vehicle 10 includes a motor 102 mounted to the body 101. The motor 102 may include a combustion engine, an electric motor, or a hybrid system combining an internal combustion engine (usually fueled by gasoline or diesel) with an electric motor, or the like. Accordingly, in some embodiments, the vehicle 10 may include not only conventional fuel vehicles but also electric vehicles or other vehicles that run on clean energy.

In the embodiment, the display device 100 shown in FIG. 1 may represent a portion of the display device 100. The display device 100 shown in FIG. 1 may represent a display panel among a plurality of components included in the display device 100. In detail, for example, the display device 100 shown in FIG. 1 may represent at least a portion of an active area and at least a portion of a non-active area of the display panel. Components of the display device 100 other than the components shown in FIG. 1 may be mounted in the interior (or in at least a portion of the interior) of the vehicle 10.

In the embodiment, the display device 100 shown in FIG. 1 may be divided into a cluster area, a center information display (CID) area, and a co-driver display (CDD) area. Separate display devices may be mounted for the respective areas. Alternatively, one display device may be mounted so as to extend from the cluster area to the CDD area. Although one display device 100 is illustrated in FIG. 1 as being mounted so as to extend from the cluster area to the CDD area, the disclosure is not limited thereto. One or more display devices may be mounted so as to cover the cluster area, the CID area, and the CDD area.

In order to prevent an image displayed in a portion of the CID area or the CDD area from attracting the attention of the driver of the vehicle, viewing angles of some areas of the display device 100 may be controlled to restrict the driver of the vehicle from viewing images.

Therefore, a predetermined area of the display device 100 mounted in the vehicle may have a function of controlling a viewing angle in order to limit viewing thereof by the driver.

FIG. 2 is a cross-sectional view of the display device according to the embodiment of the present disclosure. The pixel configuration for control of a viewing angle in the above-described display device 100 will be described with reference to FIG. 2.

As shown in FIG. 2, the display device 100 according to the embodiment of the present disclosure may include a substrate 110, a plurality of first light-emitting devices De1, a plurality of second light-emitting devices De2, an encapsulation layer 190, a light-blocking pattern 210, an optical gap layer 220, a lens layer 230, a planarization layer 240, and a polarization layer 250.

A plurality of sub-pixels SP1, SP2, and SP3 is defined on the substrate 110. For example, a first sub-pixel SP1, a second sub-pixel SP2, and a third sub-pixel SP3 are defined on the substrate 110. Each of the first sub-pixel SP1, the second sub-pixel SP2, and the third sub-pixel SP3 includes a first emission area EA1 and a second emission area EA2.

The first light-emitting device De1 is provided in the first emission area EA1, and the second light-emitting device De2 is provided in the second emission area EA2.

The first sub-pixel SP1, the second sub-pixel SP2, and the third sub-pixel SP3 may be a red sub-pixel, a green sub-pixel, and a blue sub-pixel, respectively. For example, the first light-emitting device De1 and the second light-emitting device De2 of the first sub-pixel SP1 may emit red light, the first light-emitting device De1 and the second light-emitting device De2 of the second sub-pixel SP2 may emit green light, and the first light-emitting device De1 and the second light-emitting device De2 of the third sub-pixel SP3 may emit blue light.

The encapsulation layer 190 is provided on the first light-emitting device De1 and the second light-emitting device De2. The encapsulation layer 190 has a flat upper surface. The encapsulation layer 190 may protect the first light-emitting device De1 and the second light-emitting device De2 from moisture and oxygen.

The light-blocking pattern 210 is provided on the encapsulation layer 190. The light-blocking pattern 210 is formed corresponding to a region between adjacent sub-pixels SP1, SP2, and SP3 and/or a region between the first emission area EA1 and the second emission area EA2 of each sub-pixel SP1, SP2, and SP3.

The light-blocking pattern 210 may be a black matrix. For example, the light-blocking pattern 210 may be made of black resin, chromium oxide, or the like. Alternatively, the light-blocking pattern 210 may be a touch electrode. For example, the light-blocking pattern 210 may be made of metal. In this case, the touch electrode may include a plurality of transmitting electrodes and a plurality of receiving electrodes intersecting each other, and may detect touch by variation in capacitance between the plurality of transmitting electrodes and the plurality of receiving electrodes.

The optical gap layer 220 is provided on the light-blocking pattern 210. The optical gap layer 220 secures an optical gap between the first and second light-emitting devices De1 and De2 and lenses 232 and 234 of the lens layer 230 to improve the efficiency of the lenses 232 and 234. For example, light from the first and second light-emitting devices De1 and De2 may be refracted in a specific direction by the lenses 232 and 234. The optical gap layer 220 may have a thickness ranging from several to tens of micrometers (m). The optical gap layer 220 may be made of an organic insulating material. For example, the optical gap layer 220 may be made of photo acryl, benzocyclobutene (BCB), polyimide (PI), or polyamide (PA). However, the disclosure is not limited thereto.

The lens layer 230 is provided on the optical gap layer 220. The lens layer 230 includes a first lens 232 and a second lens 234. The first lens 232 is disposed on the first emission area EA1 to refract light from the first light-emitting device De1 in a specific direction. The second lens 234 is disposed on the second emission area EA2 to refract light from the second light-emitting device De2 in a specific direction. A portion of each of the first lens 232 and the second lens 234 may overlap the light-blocking pattern 210.

The first lens 232 is a half-spherical lens, and the second lens 234 is a half-cylindrical lens. For example, first light L1 emitted from the first light-emitting device De1 of each of the sub-pixels SP1, SP2, and SP3 is refracted and output at a specific angle by the first lens 232, and second light L2 emitted from the second light-emitting device De2 of each of the sub-pixels SP1, SP2, and SP3 is refracted and output at a specific angle by the second lens 234. In this way, the viewing angle of each of the sub-pixels SP1, SP2, and SP3 may be limited.

The planarization layer 240 is provided on the lens layer 230 to protect the first lens 232 and the second lens 234. The planarization layer 240 is made of an organic insulating material. For example, the planarization layer 240 may be made of photo acryl, benzocyclobutene (BCB), polyimide (PI), or polyamide (PA). However, the disclosure is not limited thereto. The planarization layer 240 has a flat upper surface. The refractive index of the planarization layer 240 is less than the refractive indexes of the first lens 232 and the second lens 234.

The polarization layer 250 is provided on the planarization layer 240. The polarization layer 250 may include a linear polarization layer and a retardation layer. The polarization layer 250 may convert the polarization state of external light incident on the display device 100, thereby preventing the external light from being reflected from the display device 100 and then emitted back to the outside.

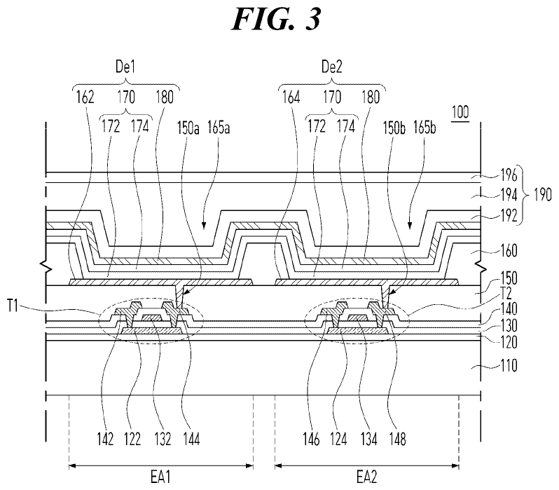

An emission area of a display device according to an embodiment of the present disclosure will be described with reference to FIG. 3.

FIG. 3 is a cross-sectional view of an emission area of the display device according to the embodiment of the present disclosure.

As shown in FIG. 3, a display device 100 according to an embodiment of the present disclosure includes a substrate 110, a plurality of transistors T1 and T2, a plurality of light-emitting devices De1 and De2, and an encapsulation layer 190.

In detail, each of the sub-pixels SP1, SP2, and SP3 on the substrate 110 includes a first emission area EA1 and a second emission area EA2. The substrate 110 may be a glass substrate or a plastic substrate. For example, polyimide (PI) may be used for a plastic substrate. However, the disclosure is not limited thereto.

A buffer layer 120 is formed on the substrate 110. The buffer layer 120 is located on substantially the entire surface of the substrate 110. The buffer layer 120 blocks movement of moisture or foreign substances from the substrate 110 to the transistors T1 and T2. The buffer layer 120 may be formed of an inorganic material, such as silicon oxide (SiO₂) and silicon nitride (SiNx). The buffer layer 120 may take the form of a single layer or multiple layers.

A first semiconductor layer 122 and a second semiconductor layer 124 which are patterned are formed on the buffer layer 120 of the first emission area EA1 and the second emission area EA2, respectively. Each of the first semiconductor layer 122 and the second semiconductor layer 124 may be independently made of an oxide semiconductor material or polycrystalline silicon.

If the first semiconductor layer 122 and the second semiconductor layer 124 are made of an oxide semiconductor material, a shield pattern may be additionally formed below the same. The shield pattern blocks incidence of light on the first semiconductor layer 122 and the second semiconductor layer 124, thereby preventing the first semiconductor layer 122 and the second semiconductor layer 124 from being deteriorated by light.

On the other hand, if the first semiconductor layer 122 and the second semiconductor layer 124 are made of polycrystalline silicon, both edges of each of the first semiconductor layer 122 and the second semiconductor layer 124 may be doped with an impurity.

A gate insulating layer 130 made of an insulating material is disposed on the first semiconductor layer 122 and the second semiconductor layer 124. In FIG. 2, the gate insulating layer 130 is formed on substantially the entire surface of the substrate 110. However, in another example, the gate insulating layer 130 may be patterned in the same shape as a first gate electrode 132 and a second gate electrode 134.

The gate insulating layer 130 may be made of an inorganic insulating material, such as silicon oxide (SiO₂) and silicon nitride (SiNx). If the first semiconductor layer 122 and the second semiconductor layer 124 are made of an oxide semiconductor material, the gate insulating layer 130 may be made of silicon oxide SiO₂. On the other hand, if the first semiconductor layer 122 and the second semiconductor layer 124 are made of polycrystalline silicon, the gate insulating layer 130 may be made of silicon oxide (SiO₂) or silicon nitride (SiNx).

A first gate electrode 132 and a second gate electrode 134 are formed on the gate insulating layer 130 so as to correspond to the first semiconductor layer 122 and the second semiconductor layer 124, respectively. The first gate electrode 132 and the second gate electrode 134 are made of a conductive material, such as metal. In addition, a gate line may be formed on the gate insulating layer 130. The gate line may extend in one direction.

An interlayer insulating layer 140 is formed on the first gate electrode 132 and the second gate electrode 134 over substantially the entire surface of the substrate 110. The interlayer insulating layer is made of an insulating material. The interlayer insulating layer 140 may be formed of an inorganic insulating material, such as silicon oxide (SiO₂) and silicon nitride (SiNx), or may be formed of an organic insulating material such as photo acryl and benzocyclobutene.

The interlayer insulating layer 140 includes contact holes exposing both sides of the upper surface of each of the first semiconductor layer 122 and the second semiconductor layer 124. The contact holes may also be formed in the gate insulating layer 130. A first source electrode 142 and a first drain electrode 144 are formed on the interlayer insulating layer 140 in the first emission area EA1, and a second source electrode 146 and a second drain electrode 148 are formed on the interlayer insulating layer 140 in the second emission area EA2. The first source electrode 142, the first drain electrode 144, the second source electrode 146 and the second drain electrode 148 are made of a conductive material, such as metal. In addition, a data line and a power line may be formed on the interlayer insulating layer 140 so as to extend in a direction perpendicular to the direction in which the gate line extends.

The first source electrode 142 and the first drain electrode 144 are in contact with both sides of the first semiconductor layer 122 through the contact holes in the interlayer insulating layer 140, and the second source electrode 146 and the second drain electrode 148 are in contact with both sides of the second semiconductor layer 124 through the contact holes in the interlayer insulating layer 140. The data line extends in the direction perpendicular to the direction in which the gate line extends to intersect the gate line, thereby defining a pixel area corresponding to each sub-pixel, and the power line, which supplies high-potential voltage, is located so as to be spaced apart from the data line.

The first semiconductor layer 122, the first gate electrode 132, the first source electrode 142, and the first drain electrode 144 form the first transistor T1, and the second semiconductor layer 124, the second gate electrode 134, the second source electrode 146, and the second drain electrode 148 form the second transistor T2.

At least one transistor having the same structure as the first transistor T1 and the second transistor T2 may be additionally formed on the substrate 110 of each sub-pixel. However, the disclosure is not limited thereto.

A protective layer 150 is formed on the first source electrode 142, the first drain electrode 144, the second source electrode 146, and the second drain electrode 148 over substantially the entire surface of the substrate 110. The protective layer 150 is made of an insulating material. The protective layer 150 may be formed of an organic insulating material, such as photo acryl and benzocyclobutene. The protective layer 150 includes a flat upper surface.

An insulating layer made of an inorganic insulating material, such as silicon oxide (SiO₂) and silicon nitride (SiNx) may be additionally formed beneath the protective layer 150. For example, at least one insulating layer including an inorganic insulating material may be disposed between the first transistor T1 and the protective layer 150 and between the second transistor T2 and the protective layer 150.

The protective layer 150 includes a first drain contact hole 150a and a second drain contact hole 150b exposing the first drain electrode 144 and the second drain electrode 148, respectively.

A first anode electrode 162 and a second anode electrode 164 are formed on the protective layer 150. The first anode electrode 162 and the second anode electrode 164 are made of a material having a relatively high work function. The first anode electrode 162 is located in the first emission area EA1 and is in contact with the first drain electrode 144 through the first drain contact hole 150a. The second anode electrode 164 is located in the second emission area EA2 and is in contact with the second drain electrode 148 through the second drain contact hole 150b.

For example, each of the first anode electrode 162 and the second anode electrode 164 may be made of a transparent conductive material such as indium tin oxide (ITO) or indium zinc oxide (IZO). However, the disclosure is not limited thereto.

The display device 100 according to the embodiment of the present disclosure may be of a top emission type in which light from the plurality of light-emitting devices De1 and De2 is output in a direction opposite to the substrate 110. Thus, each of the first anode electrode 162 and the second anode electrode 164 may further include a reflective electrode or a reflective layer made of a highly reflective metal material beneath a layer made of a transparent conductive material. For example, the reflective electrode or the reflective layer may be made of an aluminum-palladium-copper (APC) alloy, silver (Ag), or aluminum (Al). In this case, each of the first anode electrode 162 and the second anode electrode 164 may have a triple-layered structure of ITO/APC/ITO, ITO/Ag/ITO, or ITO/Al/ITO. However, the disclosure is not limited thereto.

A bank layer 165 is formed on the first anode electrode 162 and the second anode electrode 164. The bank layer 165 is made of an insulating material. For example, the bank layer 165 may be made of polyimide resin, acrylic resin, or benzocyclobutene resin. However, the disclosure is not limited thereto. In the present disclosure, the bank layer 165 may have a single-layered structure or a double-layered structure. For example, the bank layer 165 may have a double-layered structure including a lower hydrophilic bank layer and an upper hydrophobic bank layer.

The bank layer 165 overlaps the edges of the first anode electrode 162 and the second anode electrode 164. The bank layer 165 covers an edge of each of the first anode electrode 162 and the second anode electrode 164. The bank layer 165 includes a first opening 165a and a second opening 165b to expose a portion of each of the first anode electrode 162 and the second anode electrode 164.

The bank layer 165 included in at least one of the first sub-pixel SP1, the second sub-pixel SP2, and the third sub-pixel SP3 may further include a third opening that additionally exposes at least one of the first anode electrode 162 and the second anode electrode 164. The bank layer including the third opening will be described later in more detail.

An emission unit 170 is formed on the first anode electrode 162 and the second anode electrode 164 exposed through the first opening 165a and the second opening 165b in the bank layer 165. The emission unit 170 may include an organic layer 172 and an emission layer 174 located between the first anode electrode 162 and the second anode electrode 164.

The organic layer 172 is a functional layer to improve the luminous efficiency of the emission layer 174. For example, the organic layer 172 may include at least one of a hole injection layer (HIL) that facilitates injection of holes, a hole transport layer (HTL) that facilitates transport of holes, an electron injection layer (EIL) that facilitates injection of electrons from a cathode electrode 180, and an electron transport layer (ETL) that facilitates transport of electrons. The organic layer 172 may be formed as one layer in each of the sub-pixels SP1, SP2, and SP3. The organic layer 172 may be formed as one layer over the entirety of each of the sub-pixels SP1, SP2, and SP3. That is, the organic layers 172 of the sub-pixels SP1, SP2, and SP3 may be connected to each other to form an integrated common layer. The organic layer 172 is disposed beneath the emission layer 174, as shown in FIG. 3. However, the organic layer 172 may be disposed above the emission layer 174 depending on the type of the emission layer 174. For example, the hole injection layer (HIL) and the hole transport layer (HTL) may be disposed beneath the emission layer 174, and the electron injection layer (EIL) and the electron transport layer (ETL) may be disposed above the emission layer 174.

The emission layer 174 may be made of one of a red light-emitting material, a green light-emitting material, and a blue light-emitting material. However, the disclosure is not limited thereto. The light-emitting material may be an organic light-emitting material, such as a phosphorescent compound and a fluorescent compound. However, the disclosure is not limited thereto. For example, an inorganic light-emitting material such as a quantum dot may be used.

The emission layer 174 on the first anode electrode 162 and the emission layer 174 on the second anode electrode 164 are connected to each other to be integrated. However, the disclosure is not limited thereto. The emission layer 174 on the first anode electrode 162 and the emission layer 174 on the second anode electrode 164 may be separated from each other.

The emission layer 174 may be formed through an evaporation process. In this case, a fine metal mask (FMM) may be used in order to pattern the emission layer 174 in each sub-pixel. Alternatively, the emission layer 174 may be formed through a solution process. In this case, the emission layer 174 may be provided only within the first opening 165a and the second opening 165b. At a position near the bank layer 165, the height of the emission layer 174 may gradually increase in a direction approaching the bank layer 165.

A cathode electrode 180 is formed on the emission unit 170 over substantially the entire surface of the substrate 110. The cathode electrode 180 is made of a conductive material having a relatively low work function. For example, the cathode electrode 180 may be formed of aluminum, magnesium, silver, or an alloy thereof. In this case, the cathode electrode 180 has a relatively small thickness to allow light from the emission unit 170 to pass therethrough. Alternately, the cathode electrode 180 may be formed of a transparent conductive material such as indium-gallium-oxide (IGO). However, the disclosure is not limited thereto.

The first anode electrode 162, the emission unit 170, and the cathode electrode 180 in the first emission area EA1 form the first light-emitting device De1, and the second anode electrode 164, the emission unit 170, and the cathode electrode 180 in the second emission area EA2 form the second light-emitting device De2.

The display device 100 according to the embodiment of the present disclosure may be of a top emission type in which light from the emission unit 170 of the first light-emitting device De1 and the emission unit 170 of the second light-emitting device De2 is output in a direction opposite to the substrate 110. For example, the light from the emission unit 170 of the first light-emitting device De1 and the emission unit 170 of the second light-emitting device De2 may be emitted outside through the cathode electrode 180. A top emission type may have a wider emission area than a bottom emission type having the same size. Thus, the display device 100 according to the embodiment of the present disclosure may exhibit improved luminance and reduced power consumption.

An encapsulation layer 190 is formed on the cathode electrode 180 over substantially the entire surface of the substrate 110. The encapsulation layer 190 prevents external moisture and/or oxygen from entering the first light-emitting device De1 and the second light-emitting device De2. The encapsulation layer 190 may be formed of a single layer or multiple layers. For example, the encapsulation layer 190 may have a stacked structure of a first inorganic layer 192, an organic layer 194, and a second inorganic layer 196. The organic layer 194 may be a layer that blocks foreign substances generated during the manufacturing process.

As described above, in the display device 100 according to the embodiment of the present disclosure, each of the sub-pixels SP1, SP2, and SP3 includes the first emission area EA1 and the second emission area EA2, the half-spherical first lens 232 is disposed on the first emission area EA1 of each sub-pixel SP1, SP2, and SP3, and the half-cylindrical second lens 234 is disposed on the second emission area EA2 of each sub-pixel SP1, SP2, and SP3. Therefore, in the display device 100 according to the embodiment of the present disclosure, the viewing angle may be limited.

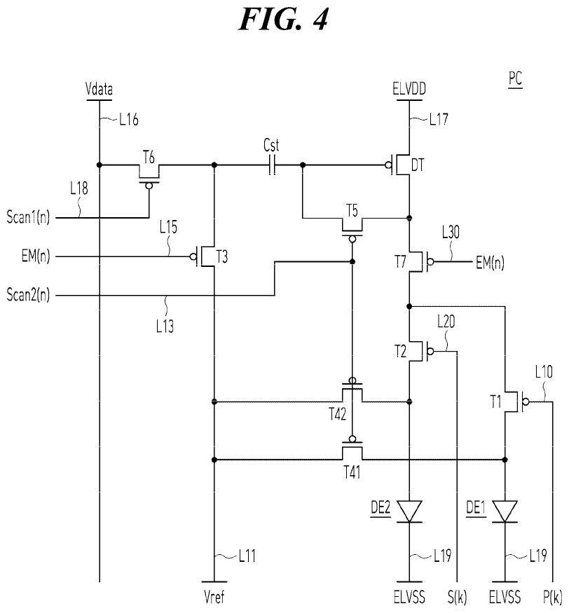

FIG. 4 is a driving circuit diagram of a pixel according to an embodiment of the present disclosure. Referring to FIG. 4, a pixel circuit PC may include nine transistors and one capacitor.

The pixel circuit PC may include a first transistor T1, a second transistor T2, a third transistor T3, a 4-1^{st} transistor T41, a 4-2^{nd} transistor T42, a fifth transistor T5, a sixth transistor T6, a seventh transistor T7, a driving transistor DT, and a capacitor Cst.

At least some of the nine transistors included in the pixel circuit PC may be n-type transistors or p-type transistors. In the case of a p-type transistor, a low-level voltage of each driving signal may be a voltage for turning on the TFT, and a high-level voltage of each driving signal may be a voltage for turning off the TFT.

Here, the low-level voltage may correspond to a predetermined voltage lower than the high-level voltage. For example, the low-level voltage may include a voltage in a range of −8 V to −12 V. The high-level voltage may correspond to a predetermined voltage higher than the low-level voltage. For example, the high-level voltage may include a voltage in a range of 12 V to 16 V. In some embodiments, the low-level voltage may be referred to as a first voltage, and the high-level voltage may be referred to as a second voltage. In this case, the first voltage may have a value lower than the second voltage. However, the aforementioned ranges of the low-level voltage and the high-level voltage are merely given by way of example, and the disclosure is not limited thereto.

A first electrode or a second electrode of a transistor, which will be described below, may be a source electrode or a drain electrode. However, the terms “first electrode” and “second electrode” are merely used to distinguish one electrode from another, and do not limit what the respective electrodes correspond to. Further, first electrodes of the respective transistors may not be the same electrode. For example, the first electrode of the first transistor T1 may be a source electrode of the first transistor T1, and the first electrode of the sixth transistor T6 may be a drain electrode of the sixth transistor T6.

In the embodiment, the driving transistor DT may be connected to the first transistor T1 connected to the first light-emitting device De1 and the second transistor T2 connected to the second light-emitting device De2. For example, the second electrode of the driving transistor DT may be connected to the first transistor T1 and the second transistor T2.

In the embodiment, the driving transistor DT may be connected to a first power line L17 that provides a high-potential power voltage ELVDD. For example, the first electrode of the driving transistor DT may be connected to the first power line L17. If the driving transistor DT is turned on, the high-potential power voltage ELVDD supplied through the first power line L17 may be transferred from the first electrode of the driving transistor DT to the second electrode of the driving transistor DT.

In the embodiment, the first transistor T1 may be connected to at least one of the first light-emitting device De1, the second transistor T2, the 4-1^{st} transistor T41, or the seventh transistor T7.

For example, the first electrode of the first transistor T1 may be connected to at least one of the second transistor T2 or the seventh transistor T7. The seventh transistor T7 may be connected to the driving transistor DT and the fifth transistor T5. The second electrode of the first transistor T1 may be connected to at least one of the first light-emitting device De1 or the 4-1^{st} transistor T41. The gate electrode of the first transistor T1 may be connected to a first control line L10. The first transistor T1 may be turned on or off in response to a first control signal P(k) provided through the first control line L10. If the first transistor T1 is turned on, the voltage provided through the driving transistor DT and the seventh transistor T7 may be input to the first light-emitting device De1 (e.g., the anode electrode of the first light-emitting device De1).

For example, in a case in which the pixel circuit PC is disposed in a kl (where k is a positive integer) column, the first control signal P(k) may include a kl first control signal that is supplied to the k^{th} column. The first control signal P(k) may be provided by a mode control unit (or mode control circuit), and driving (or emission) of the first light-emitting device De1 on which the first lens is disposed may be controlled in response to the first control signal P(k).

In the embodiment, the second transistor T2 may be connected to at least one of the second light-emitting device De2, the first transistor T1, the 4-2^{nd} transistor T42, or the seventh transistor T7.

For example, the first electrode of the second transistor T2 may be connected to at least one of the first transistor T1 or the seventh transistor T7. The second electrode of the second transistor T2 may be connected to at least one of the 4-2^{nd} transistor T42 or the second light-emitting device De2. The seventh transistor T7 may be connected to the driving transistor DT and the fifth transistor T5. The gate electrode of the second transistor T2 may be connected to a second control line L20. The second transistor T2 may be turned on or off in response to a second control signal S(k) provided through the second control line L20. If the second transistor T2 is turned on, the voltage provided through the driving transistor DT and the seventh transistor T7 may be input to the second light-emitting device De2 (e.g., the anode electrode of the second light-emitting device De2).

For example, in a case in which the pixel circuit PC is disposed in a kl (where k is a positive integer) column, the second control signal S(k) may include a kl second control signal that is supplied to the k^{th} column. The second control signal S(k) may be provided by a mode control unit (or mode control circuit), and driving (or emission) of the second light-emitting device De2 on which the second lens is disposed may be controlled in response to the second control signal S(k).

In the embodiment, the first lens may be disposed on the first light-emitting device De1. The viewing angle of the area in which the first light-emitting device De1 is disposed may correspond to a first value due to the first lens. For example, the viewing angle of the area in which the first light-emitting device De1 is disposed may be equal to or less than the first value. The second lens may be disposed on the second light-emitting device De2. The viewing angle of the area in which the second light-emitting device De2 is disposed may correspond to a second value due to the second lens. The second value may be greater than the first value. For example, the viewing angle of the area in which the second light-emitting device De2 is disposed may be equal to or greater than the second value.

In the embodiment, the area in which the first light-emitting device De1 of the pixel circuit PC is disposed may have a viewing angle corresponding to the first value within which light is provided over a region corresponding to the front passenger seat. The area in which the second light-emitting device De2 is disposed may have a viewing angle corresponding to the second value within which light is provided over a region corresponding to the front passenger seat and a region corresponding to the driver's seat disposed next to the front passenger seat.

In the embodiment, the third transistor T3 may be connected to at least one of the 4-1^{st} transistor T41, the 4-2^{nd} transistor T42, the sixth transistor T6, or the capacitor Cst.

For example, the first electrode of the third transistor T3 may be connected to the sixth transistor T6 and the capacitor Cst. The second electrode of the third transistor T3 may be connected to the 4-1^{st} transistor T41 and the 4-2^{nd} transistor T42. The gate electrode of the third transistor T3 may be connected to an emission signal line L15 that supplies an emission signal EM(n). In a case in which the pixel circuit PC is disposed in an n^{th} (where n is a positive integer) pixel row, the emission signal EM(n) may correspond to an n^{th} emission signal EM(n) that is supplied to the n^{th} row. The third transistor T3 may be turned on or off in response to the emission signal EM(n). The second electrode of the third transistor T3 may be connected to a reference voltage line L11 that supplies a reference voltage Vref, for example, a second power line.

In the embodiment, the 4-1^{st} transistor T41 may be connected to at least one of the first transistor T1, the third transistor T3, or the first light-emitting device De1.

For example, the first electrode of the 4-1^{st} transistor T41 may be connected to the third transistor T3. The second electrode of the 4-1^{st} transistor T41 may be connected to the first transistor T1 and the first light-emitting device De1. The gate electrode of the 4-1^{st} transistor T41 may be connected to an n^{th} second scan line L13. Accordingly, the 4-1^{st} transistor T41 may receive an n^{th} second scan signal Scan2(n) and may be turned on or off in response to the n^{th} second scan signal Scan2(n).

In the embodiment, the 4-2^{nd} transistor T42 may be connected to at least one of the second transistor T2, the third transistor T3, or the second light-emitting device De2.

For example, the first electrode of the 4-2^{nd} transistor T42 may be connected to the third transistor T3. The second electrode of the 4-2^{nd} transistor T42 may be connected to the second transistor T2 and the second light-emitting device De2. The gate electrode of the 4-2^{nd} transistor T42 may be connected to the n^{th} second scan line L13. Accordingly, the 4-2^{nd} transistor T42 may receive the n^{th} second scan signal Scan2(n) and may be turned on or off in response to the n^{th} second scan signal Scan2(n).

In the embodiment, the fifth transistor T5 may be connected to at least one of the driving transistor DT, the 4-1^{st} transistor T41, the 4-2^{nd} transistor T42, the capacitor Cst, or the seventh transistor T7.

For example, the first electrode of the fifth transistor T5 may be connected to the driving transistor DT and the capacitor Cst. The second electrode of the fifth transistor T5 may be connected to the driving transistor DT and the seventh transistor T7. The gate electrode of the fifth transistor T5 may be connected to the n^{th} second scan line L13 that supplies the second scan signal Scan2(n) in the n^{th} row. The fifth transistor T5 may receive the n^{th} second scan signal Scan2(n) and may be turned on or off in response to the n^{th} second scan signal Scan2(n).

In some embodiments, an n^{th} first scan line L18 may provide an n^{th} first scan signal. In this case, the n^{th} first scan signal may be provided to the gate electrode of the sixth transistor T6. The n^{th} second scan line L13 may provide the n^{th} second scan signal. In this case, the n^{th} second scan signal may be provided to the gate electrode of each of the 4-1^{st} transistor T41, the 4-2^{nd} transistor T42, and the fifth transistor T5.

In the embodiment, the sixth transistor T6 may be connected to at least one of the third transistor T3 or the capacitor Cst.

For example, the first electrode of the sixth transistor T6 may be connected to the third transistor T3 and the capacitor Cst. The second electrode of the sixth transistor T6 may be connected to a data line L16 that supplies a data voltage Vdata. The gate electrode of the sixth transistor T6 may be connected to the n^{th} first scan line L18 that supplies the n^{th} first scan signal Scan1(n). The sixth transistor T6 may receive the n^{th} first scan signal Scan1(n) and may be turned on or off in response to the n^{th} first scan signal Scan1(n). If the sixth transistor T6 is turned on, the data voltage Vdata may be transferred from the second electrode thereof to the first electrode thereof.

In the embodiment, the seventh transistor T7 may be connected to at least one of the first transistor T1, the second transistor T2, the fifth transistor T5, or the driving transistor DT.

For example, the first electrode of the seventh transistor T7 may be connected to at least one of the fifth transistor T5 or the driving transistor DT. The second electrode of the seventh transistor T7 may be connected to at least one of the first transistor T1 or the second transistor T2. The gate electrode of the seventh transistor T7 may be connected to an emission signal line L30 that provides an emission signal EM(n). The seventh transistor T7 may be turned on or off in response to the emission signal EM(n). If the seventh transistor T7 is turned on, voltage (or current) may be provided from the first electrode of the seventh transistor T7 to the second electrode thereof.

In the embodiment, the first light-emitting device De1 and/or the second light-emitting device De2 may be connected to a third power line L19 that supplies a low-potential power voltage ELVSS. For example, the cathode electrode of the first light-emitting device De1 and the cathode electrode of the second light-emitting device De2 may be connected to the third power line L19 to receive the low-potential power voltage ELVSS.

In some embodiments, the low-potential power voltage may be a ground voltage (e.g., 0 volts (V)). For example, the cathode electrode of the first light-emitting device De1 and the cathode electrode of the second light-emitting device De2 may receive a voltage corresponding to ground. However, the disclosure is not limited thereto.

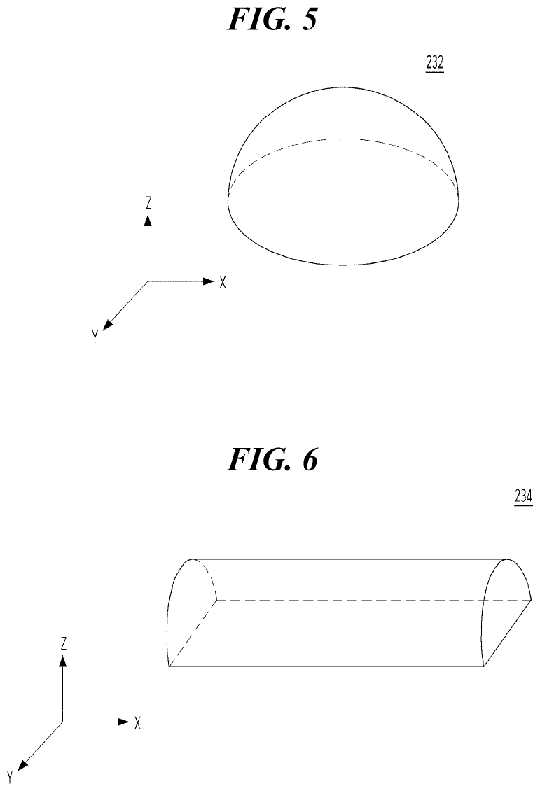

Hereinafter, a means for selectively implementing a share mode, which is a wide viewing angle mode, and a private mode, which is a narrow viewing angle mode, will be described with reference to FIGS. 5 and 6.

FIGS. 5 and 6 are perspective views of lenses according to an embodiment of the present disclosure. FIG. 5 schematically shows the first lens 232 of the display device according to the embodiment of the present disclosure, and FIG. 6 schematically shows the second lens 234 of the display device according to the embodiment of the present disclosure.

As shown in FIG. 5, the first lens 232 is a half-spherical lens having a semicircular section in an X direction and a Y direction. Accordingly, the first lens 232 limits the viewing angle in the X and Y directions. For example, the first emission area EA1 provided with the half-spherical first lens 232 may have a narrow viewing angle of 30 degrees or less both in an upward-downward direction and in a leftward-rightward direction.

On the other hand, as shown in FIG. 6, the second lens 234 is a half-cylindrical lens having a rectangular section in the X direction and a semicircular section in the Y direction. Accordingly, the second lens 234 limits the viewing angle in the Y direction, but does not limit the viewing angle in the longitudinal direction of the second lens 234, i.e., the X direction. For example, the second emission area EA2 provided with the half-cylindrical second lens 234 may have a narrow viewing angle of 30 degrees or less in the upward-downward direction and a wide viewing angle of 60 degrees or more in the leftward-rightward direction.

As shown in FIGS. 5 and 6, both the first lens 232 and the second lens 234 limit the viewing angle in the Y direction (implement an upward/downward narrow viewing field mode at all times). The reason for this is that, when the display device 100 is applied to a vehicle, there is need to limit the viewing angle in the upward-downward direction in order to prevent an image from being reflected on a front windshield of the vehicle and thus disturbing the front field of view of the driver.

In this way, the upward/downward narrow viewing field mode and the leftward/rightward narrow viewing field mode may be implemented by driving of the first emission area EA1, and the upward/downward narrow viewing field mode and the leftward/rightward wide viewing field mode may be implemented by driving of the second emission area EA2.

That is, the light-emitting display device according to the embodiment of the present disclosure may always implement the narrow viewing field mode in the upward-downward direction and may selectively implement the wide viewing field mode and the narrow viewing field mode in the leftward-rightward direction using the first lens 232 and the second lens 234.

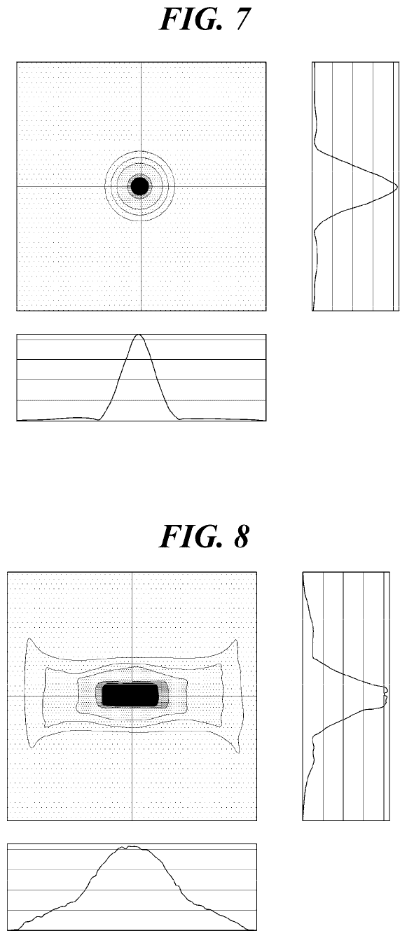

Regarding such implementation of the wide viewing field mode and the narrow viewing field mode, the viewing angle characteristics of the first lens 232 and the second lens 234 will be described in detail with reference to FIGS. 7 and 8.

FIG. 7 is a diagram showing an optical profile for the viewing angle of the first lens of the display device according to the embodiment of the present disclosure, and FIG. 8 is a diagram showing an optical profile for the viewing angle of the second lens of the display device according to the embodiment of the present disclosure.

As shown in FIGS. 7 and 8, while the first emission area EA1 provided with the half-spherical first lens 232 has a narrow viewing angle of 30 degrees or less both in the upward-downward direction and in the leftward-rightward direction, the second emission area EA2 provided with the half-cylindrical second lens 234 has a narrow viewing angle of 30 degrees or less in the upward-downward direction and a wide viewing angle of 60 degrees or more in the leftward-rightward direction.

Therefore, the upward/downward narrow viewing field mode and the leftward/rightward narrow viewing field mode may be implemented by driving of the first emission area EA1, and the upward/downward narrow viewing field mode and the leftward/rightward wide viewing field mode may be implemented by driving of the second emission area EA2.

That is, the display device according to the embodiment of the present disclosure may always implement the narrow viewing field mode in the upward-downward direction and may selectively implement the wide viewing field mode and the narrow viewing field mode in the leftward-rightward direction using the first and second lenses 232 and 234.

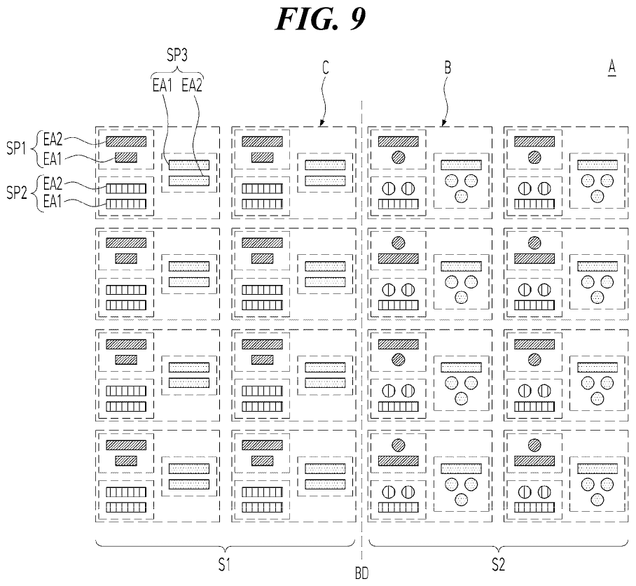

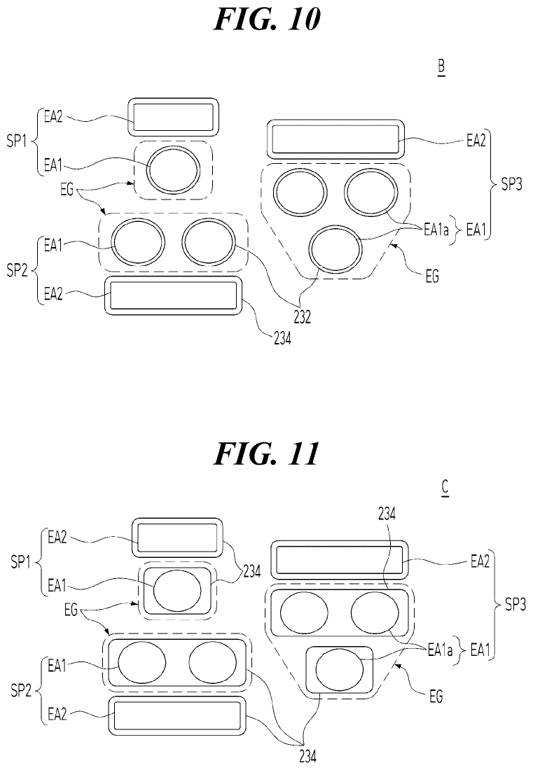

FIG. 9 is an enlarged plan view of the display device according to the embodiment of the present disclosure, and FIGS. 10 to 12 are enlarged plan views of area B and area C shown in FIG. 9.

In order to prevent images displayed on some areas of the display device 100 from being viewed from a specific direction, the viewing angle of the corresponding areas of the display device 100 may be controlled by the above-described configuration. A configuration for preventing recognition of a boundary between an area in which the viewing angle control function is implemented and an area in which the viewing angle control function is not implemented will be described with reference to FIGS. 9 to 12.

The display device 100 may include a first area S1 and a second area S2. As will be described later, the first area S1 and the second area S2 may be areas adjacent to each other with a boundary BD therebetween, the first area S1 may be a CID area or a cluster area in which the viewing angle control function is not implemented, and the second area S2 may be a CDD area in which the viewing angle control function is implemented.

The first area S1 and the second area S2 may be distinguished from each other based on the presence or absence of the viewing angle control function. Both the first area and the second area may be included in the CDD area.

As described above, each of the first sub-pixel SP1, the second sub-pixel SP2, and the third sub-pixel SP3 may include at least one first emission area EA1 and at least one second emission area EA2, and the first lens 232 or the second lens 234 may be disposed on each of the emission areas, such that the share mode or the private mode is implemented through individual emission control of the emission area.

To this end, each of the sub-pixels is divided into a plurality of emission areas. However, if the above-described configuration is applied to the first area S1, in which there is no need to control the viewing angle, the light-emitting area and the brightness may be reduced compared to a pixel composed of one emission area.

In order to solve this problem, referring to FIG. 9, the display device 100 may include the first area S1 in which control of the viewing angle is unnecessary and the second area S2 in which control of the viewing angle is necessary, and the first area S1 and the second area S2 may include sub-pixels having different configurations with respect to the boundary BD therebetween.

The sub-pixels in the first area S1, in which control of the viewing angle is unnecessary, include only the second lens 234, and thus are more advantageous in terms of viewing angle and brightness.

First, the pixel configuration of area B included in the second area S2 in which the viewing angle control function is implemented will be described in more detail with reference to FIG. 10.

As shown in FIG. 10, the pixel of the display device according to the embodiment may include the first, second, and third sub-pixels SP1, SP2, and SP3, and the first, second, and third sub-pixels SP1, SP2, and SP3 may be red, green, and blue sub-pixels, respectively.

Each of the first, second, and third sub-pixels SP1, SP2, and SP3 includes at least a first emission area EA1 and a second emission area EA2. The first emission area EA1 of each of the first, second, and third sub-pixels SP1, SP2, and SP3 may include at least one sub-emission area EA1a. The sub-emission area EA1a corresponds to the first lens 232, and the second emission area EA2 corresponds to the second lens 234.

The first and second sub-pixels SP1 and SP2 are disposed in the Y direction, and the third sub-pixel SP3 is disposed in the X direction with respect to the first and second sub-pixels SP1 and SP2. In this case, the first emission areas EA1 of the first and second sub-pixels SP1 and SP2 may be located between the second emission area EA2 of the first sub-pixel SP1 and the second emission area EA2 of the second sub-pixel SP2. The above configuration may be reversed in the sub-pixels adjacent thereto in the Y direction, or the above configuration and the reverse configuration may be repeated.

The first emission area EA1 of the third sub-pixel SP3 may be disposed adjacent to the first emission area EA1 of the first sub-pixel SP1 and the first emission area EA1 of the second sub-pixel SP2 in the X direction, and the second emission area EA2 of the third sub-pixel SP3 may be disposed adjacent to the second emission area EA2 of the first sub-pixel SP1 in the X direction.

In this way, the sub-pixels are disposed such that the first emission areas EA1 thereof are adjacent to each other or the second emission areas EA2 thereof are adjacent to each other, thereby reducing or minimizing the occurrence of image distortion or moire when displaying an image.

Each of the first, second, and third sub-pixels SP1, SP2, and SP3 may have a polygonal shape. In this case, the shapes of the first, second, and third sub-pixels SP1, SP2, and SP3 may be different from each other. However, the disclosure is not limited thereto. The first, second, and third sub-pixels SP1, SP2, and SP3 may have various shapes.

The first, second, and third sub-pixels SP1, SP2, and SP3 have different areas. The areas of the first, second, and third sub-pixels SP1, SP2, and SP3 may be determined in consideration of the lifespan and luminous efficiency of the light-emitting device provided in each sub-pixel. Because light having a shorter wavelength has higher energy, the lifespan of the blue light-emitting device is the shortest, and the lifespan of the red light-emitting device is the longest under the condition that the light-emitting devices have the same area. Therefore, in order to make the lifespans of the light-emitting devices uniform, the area of the second sub-pixel SP2 is larger than the area of the first sub-pixel SP1 and is smaller than the area of the third sub-pixel SP3.

For example, the first, second, and third sub-pixels SP1, SP2, and SP3 may have an area ratio of 1:2.5:3. The first emission areas EA1 of the first, second, and third sub-pixels SP1, SP2, and SP3 may also have an area ratio of 1:2.5:3, and the second emission areas EA2 of the first, second, and third sub-pixels SP1, SP2, and SP3 may also have an area ratio of 1:2.5:3. Accordingly, the number of sub-emission areas EA1a of the first emission area EA1 of the second sub-pixel SP2 may be greater than the number of sub-emission areas EA1a of the first emission area EA1 of the first sub-pixel SP1 and may be less than the number of sub-emission areas EA1a of the first emission area EA1 of the third sub-pixel SP3. In detail, the first emission area EA1 of the first sub-pixel SP1 may include two sub-emission areas EA1a, the first emission area EA1 of the second sub-pixel SP2 may include five sub-emission areas EA1a, and the first emission area EA1 of the third sub-pixel SP3 may include six sub-emission areas EA1a.

The plurality of sub-emission areas EA1a may be pixel groups EG sharing one pixel electrode. In this case, two sub-emission areas EA1a of the first sub-pixel SP1 and three sub-emission areas EA1a of the second sub-pixel SP2 may be disposed substantially parallel to each other in the X direction, four sub-emission areas EA1a of the third sub-pixel SP3 and one sub-emission area EA1a of the second sub-pixel SP2 may be disposed substantially parallel to each other in the X direction, and two sub-emission areas EA1a of the third sub-pixel SP3 and one sub-emission area EA1a of the second sub-pixel SP2 may be disposed substantially parallel to each other in the X direction.

However, the disclosure is not limited thereto. The area ratio of the first, second, and third sub-pixels SP1, SP2, and SP3 and the number of sub-emission areas EA1a may vary.

On the other hand, as shown in FIG. 11, the second lens 234 may be disposed on each of the emission areas of the sub-pixels corresponding to the first area S1 in which there is no need to implement the viewing angle control function. Alternatively, one second lens 234 may be disposed on at least one emission area. For example, the second lenses 234 may be disposed on the plurality of sub-emission areas EA1a of the second sub-pixel SP2 and the third sub-pixel SP3 such that each second lens 234 covers at least one sub-emission area EA1a.

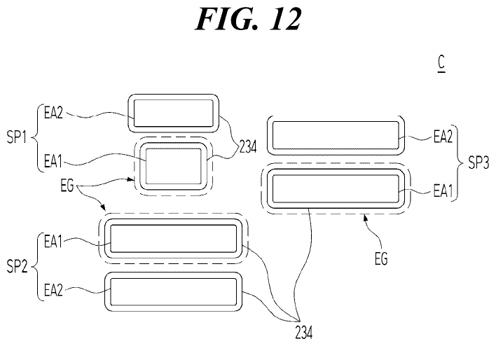

Alternatively, as shown in FIG. 12, in another embodiment of the present disclosure, each of the first emission area EA1 and the second emission area EA2, which constitute the sub-pixel, may be implemented as a single emission area corresponding to a single second lens 234.

In one example, the first emission area EA1 of the third sub-pixel SP3 shown in FIG. 11 may include a plurality of sub-emission areas EA1a. However, as shown in FIG. 12, the first emission area EA1 of the third sub-pixel SP3 may be implemented as a single emission area corresponding to one second lens 234.

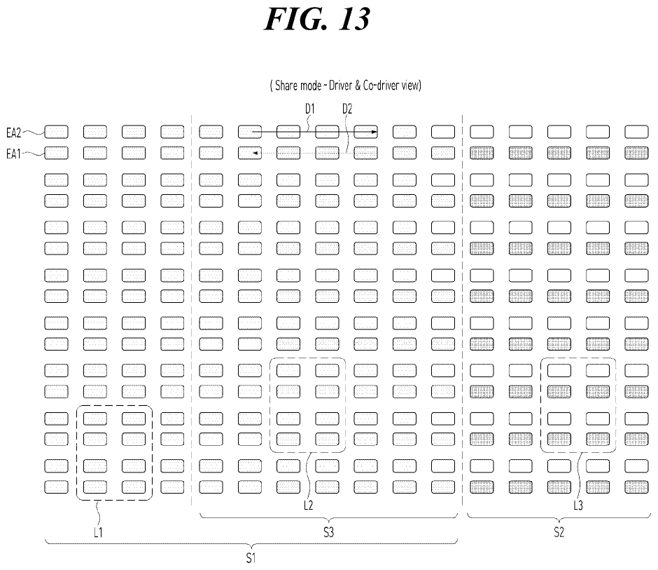

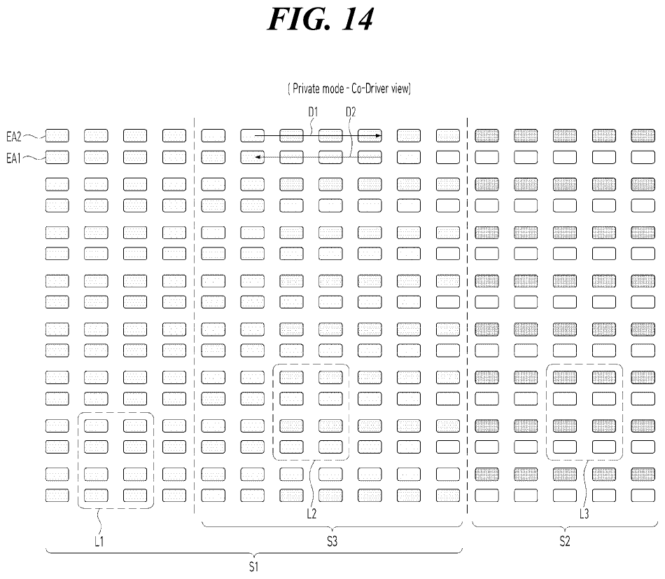

FIGS. 13 and 14 are enlarged plan views of the display device according to the embodiment of the present disclosure. In FIGS. 13 and 14, the first emission area EA1 and the second emission area EA2 are schematically shown, and illustration of the lens is omitted. The first emission area EA1 and the second emission area EA2 may be configured as shown in FIGS. 9 to 12.

A configuration for reducing or minimizing recognition of a boundary between the areas will be described with reference to FIGS. 13 and 14.

As described above, in the pixels located in the first area S1 and the second area S2, the lenses or the emission areas may be configured differently from each other in order to implement the viewing angle control function.

In the display device configured as described above, due to difference in configuration between the pixels or the lenses located in the first area S1 and the second area S2, a boundary between the two areas of the display device may be recognized by the driver or a co-driver, and thus image quality may be degraded.

Hereinafter, a configuration for reducing or minimizing recognition of the aforementioned boundary will be described. A viewing angle control mode and a share mode will be described from the viewpoint of the driver with reference to FIGS. 13 and 14.

FIG. 13 shows the display device in the share mode from the viewpoint of the driver and the co-driver. Referring to FIG. 13, the first area S1 may further include a third area S3 located adjacent to the second area S2.

The first area S1 displays an image using both the first emission area EA1 and the second emission area EA2, and the second area S2 displays an image using only the second emission area EA2.

When a direction from the third area S3 toward the second area S2 is defined as a first direction D1 and the opposite direction is defined as a second direction D2, the first emission areas in the third area S3 are driven such that brightness gradually increases in the second direction D2, and the second emission areas in the third area S3 are driven such that brightness gradually increases in the first direction D1. In the first area S1, both the first emission area EA1 and the second emission area EA2 emit light. Therefore, the first emission are EA1 and the second emission area EA2 in the first area S1 may emit light with a brightness lower than the brightness of light from the second emission area EA2 in the second area S2.

In the display device configured in this way, the average brightness of a first zone L1 in the first area S1, a third zone L3 in the second area S2, and a second zone L2 in the third area S3 becomes uniform from the viewpoint of the driver and the co-driver, whereby recognition of the boundary between the first area S1 and the second area S2 may be reduced or minimized.

A configuration of the display device for reducing or minimizing recognition of the boundary between the areas from the viewpoint of the co-driver in the viewing angle control mode will be described with reference to FIG. 14.

Referring to FIG. 14, the first area S1 may further include a third area S3 located adjacent to the second area S2.

The first area S1 displays an image using both the first emission area EA1 and the second emission area EA2, and the second area S2 displays an image using only the first emission area EA1.

When a direction from the first area S1 toward the second area S2 is defined as a first direction D1 and the opposite direction is defined as a second direction D2, the first emission areas in the third area S3 are driven such that brightness gradually decreases in the second direction D2, and the second emission areas in the third area S3 are driven such that brightness gradually decreases in the first direction D1. In the first area S1, both the first emission area EA1 and the second emission area EA2 emit light. Therefore, the first emission are EA1 and the second emission area EA2 in the first area S1 may emit light with a brightness lower than the brightness of light from the first emission area EA1 in the second area S2.

In the display device configured in this way, the average brightness of a first zone L1 in the first area S1, a third zone L3 in the second area S2, and a second zone L2 in the third area S3 becomes uniform from the viewpoint of the co-driver, whereby recognition of the boundary between the first area S1 and the second area S2 may be reduced or minimized.

As is apparent from the above description, a display device according to the present disclosure may include pixels capable of controlling a viewing angle in some areas, thereby selectively controlling the viewing angle.

The display device according to the present disclosure may use emission pixels for control of the viewing angle as general emission pixels in some areas, thereby improving the lifespan reliability of the display device.

The display device according to the present disclosure may minimize recognition of a boundary between a viewing angle control area and a general area due to difference in brightness between the two areas, thereby improving display quality.

The effects achievable through the present disclosure are not limited to the above-mentioned effects, and other various effects may be directly or implicitly disclosed in the above detailed description of the present disclosure.

Although exemplary embodiments of the present disclosure have been described for illustrative purposes, those skilled in the art will appreciate that various modifications, additions, and substitutions are possible, without departing from the scope and spirit of the disclosure as disclosed in the accompanying claims. Therefore, the embodiments disclosed in the present disclosure are intended to illustrate the scope of the technical idea of the present disclosure, and the scope of the present disclosure is not limited by the embodiments. The above embodiments are therefore to be construed in all aspects as illustrative and not restrictive. The scope of the present disclosure shall be construed on the basis of the accompanying claims, and it shall be construed that all of the technical ideas included within the scope equivalent to the claims belong to the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first area and a second area adjacent to the first area;
a first pixel in the first area, the first pixel including at least one second emission area; and
a second pixel in the second area, the second pixel including at least one first emission area and at least one second emission area,
wherein a half-spherical lens is disposed in the first emission area, and
wherein a half-cylindrical lens is disposed in the second emission area.

2. The display device according to claim 1, wherein, the first emission area in the second area is turned on, and the second emission area in the second area is turned off in a first mode.

3. The display device according to claim 2, wherein, the first emission area in the second area is turned off, and the second emission area in the second area is turned on in a second mode.

4. The display device according to claim 3, wherein the first mode is a private mode, and the second mode is a share mode.

5. The display device according to claim 4, wherein the first area further includes a third area located adjacent to the second area,
wherein the first emission area in the third area is configured to emit light such that brightness gradually increases in a direction approaching the second area in the first mode.

6. The display device according to claim 5, wherein the first emission area in the third area is configured to emit light such that brightness gradually decreases in a direction approaching the second area in the second mode.

7. The display device according to claim 6, wherein the second emission area in the third area is configured to emit light such that brightness gradually increases in a direction approaching the second area in the second mode.

8. A display device comprising:
a first area and a second area adjacent to the first area on a substrate;
a first pixel in the first area; and
a second pixel in the second area,
wherein the first pixel and the second pixel are pixels having a same color,
wherein each of the first pixel and the second pixel includes at least one emission area, and
wherein a number of the emission areas in the second pixel is greater than a number of the emission areas in the first pixel.

9. The display device according to claim 8, wherein the first pixel and the second pixel are green or blue pixels.

10. The display device according to claim 8, wherein each of the first pixel and the second pixel includes a first emission area and a second emission area,
wherein a half-cylindrical lens is disposed on the first emission area of the first pixel, and
wherein a half-spherical lens is disposed on the first emission area of the second pixel.

11. The display device according to claim 10, wherein, in a private mode, the first emission area of the second pixel is turned on, and the second emission area of the second pixel is turned off.

12. The display device according to claim 10, wherein, in a share mode, the first emission area of the second pixel is turned off, and the second emission area of the second pixel is turned on.

13. A display device comprising:
a first area and a second area adjacent to the first area on a substrate;
a first pixel in the first area;
a second pixel in the second area; and
lenses respectively corresponding to the first pixel and the second pixel,
wherein the first pixel and the second pixel have a same color, and
wherein a number of the lenses corresponding to the second pixel is greater than a number of the lenses corresponding to the first pixel.

14. The display device according to claim 13, wherein the first pixel comprises a plurality of first emission areas, and
wherein the lenses corresponding to the first pixel are configured to cover the plurality of first emission areas.

15. The display device according to claim 13, wherein the lenses corresponding to the first pixel are half-cylindrical lenses, and
wherein the lenses corresponding to the second pixel comprise a half-cylindrical lens and a half-spherical lens.

16. A vehicle comprising:
a body having a motor mounted therein;
at least one display panel in the body, the at least one display panel including:
a first area and a second area adjacent to the first area on a substrate;
a first pixel in the first area, the first pixel including at least one of a second emission area; and
a second pixel in the second area, the second pixel including at least one of a first emission area and the at least one of the second emission area,
wherein the first emission area includes a half-spherical lens, and
wherein the second emission area includes a half-cylindrical lens.
